(19) United States
(12) Patent Application Publication
(10) Pub. No.: US 2006/0018175 A1
(43) Pub. Date: Jan. 26, 2006

(54) Electrical via connection and associated contact means as well as a method for their manufacture

(75) Inventors: Rickard Liljedahl, Linkoping (SE); Goran Gustafsson, Linkoping (SE)

Correspondence Address: BIRCH STEWART KOLASCH & BIRCH, PO BOX 747, FALLS CHURCH, VA, 22040-0747, US

(73) Assignee: Thin Film Electronics ASA

(21) Appl. No.: 11/185,808

(22) Filed: Jul. 21, 2005

(30) Foreign Application Priority Data
Jul. 22, 2004 (NO) 20043180

(51) Int. Cl. G11C 7/00

(52) U.S. Cl. 365/222

(57) ABSTRACT

An electrical via connection and associated contact means in an organic electronic circuit, particularly a memory circuit is provided interfacing a layer of active organic dielectric material comprising various organic compounds. The via connection is provided in a via opening extending through the active dielectric material and connected with first and second electrical contact means on either side thereof. The second contact means comprises a first layer of chemically inert and non-reactive conducting material deposited directly on active dielectric layer, and a conducting material provided as a second layer over the first layer and in via opening down to the first contact means, creating a via connection through the active dielectric layer and connecting the first and the second contact means.—In a method for manufacturing an electric via connection and associated contact means of this kind, a first layer in a second contact means is deposited on the active dielectric layer. The first layer consists of a chemically inert and non-reactive conducting material. A via opening is formed through the active dielectric layer down to the first contact means and a second layer of the second contact means consisting of a conducting material is deposited over the first layer and in the via opening to establish the desired via connection therethrough.

The present invention concerns an electrical via connection and associated contact means in an organic electronic circuit, particularly a memory circuit, wherein a layer of an active organic dielectric material comprises fluorine atoms and consists of single molecules, oligomers, homopolymers, copolymers or blends or compounds thereof, wherein the via connection is provided in a via opening extending through the dielectric layer and is connected with first and second electrical contact means respectively provided on either side of the dielectric layer, and wherein the first contact means is provided at a bottom surface of the layer and the second contact means is provided at an opposite or top surface of the layer.

The present invention also concerns a method for manufacturing an electrical via connection and an associated contact means of this kind.

The present invention specifically addresses the problem of interfacing organic active dielectric materials comprising fluorine atoms with conductive materials forming current paths vias and electrode metal in an organic electronic circuit. The concept of an active organic dielectric material or layer as used in the present invention relates to organic dielectric materials that perform an active function in the organic electronic circuits. Examples of such materials include organic dielectric materials that can undergo a phase change when exposed to an electric field, voltage or current, or can be set in a specific physical or electrical state under such influences, for instance as in case of organic ferroelectric materials which can be set to either of two polarization states and switched therebetween. Hence active organic dielectric materials in important respects differ from passive organic dielectrics, which commonly are thought of as insulators only and will not alter their state or phase when subjected to an electric field, current or voltage. Such materials, particularly the best insulators of course have a low permittivity, but active organic dielectric materials can have a substantially higher dielectric constant and in many applications it is regarded as advantageous that the active organic dielectric material is a so-called high ε material. Nevertheless they constitute an impedance and can hence be found as active components of RC or RCL networks. A specific application which is topical in the present invention is of course the use of an active organic dielectric material in the form of ferroelectric or electret organic materials such as fluorine-containing polymers and copolymers. It has, however, turned out that when these materials are in ohmic contact with a conductor, for instance an electrode metal, and are subjected to a dynamic electrical stimulus, their functional properties can be permanently impaired. The deterioration of their functional abilities can increase with time and the number of applied stimuli, particularly when the active organic compounds comprise atoms of highly reactive elements such as fluorine.

Vias, or more properly via connections, are routinely used to connect components and devices on the opposite surfaces of layer-like structures. Most often via connections are used to connect contact means on either side of a layer-like active dielectric structure electrically and it is usually desired that the via connections shall have a minimal feature size, but at the same time be required to provide the desired high-quality electrical connection.

In integrated circuit technology based on inorganic materials via connections are usually formed of high conducting via metal with high corrosion resistance and compatibility with other inorganic conducting and dielectric materials as used with integrated circuits.

Well-functioning via connections are of great importance in VLSI circuits where thousands or even millions of connections shall be formed in topologically complex ultra-miniature structures. Contact means provided on either side of active dielectric layers require for the via connection that a via opening or via hole through the layer and with dimensions in the submicrometer range. Such via holes can be made using microphotolithographical patterning and subsequent etching. In this manner also vias with different cross section geometries can be formed.

U.S. Pat. No. 6,127,070 (Yang & al.) discloses a method for forming rectangular vias with an aspect ratio greater than 4:1. The transverse dimensions of such vias as limited by an applicable design rule is in the order of 0.2 μm, implying rectangular vias with a length about 1 μm. Different conducting materials have been proposed and are used for filling the via hole. Typically tungsten is used as via material, and the via is then referred to as a tungsten plug. In practice, however, a via plug may be formed by any suitable conducting material that can be deposited with sufficient flow rate to fill the via holes.

U.S. Pat. No. 5,322,816 (Pinter) discloses a method for making via holes in a semiconductor layer with a thickness of approximately 1 μm and wherein the transverse side edges of the vias can be formed with a slope or taper in the vertical direction. This ensures a high-quality filling of the via hole when the via metal is blanket-deposited, for instance as a sputtered film, to cover essentially the sloping side edges of the via and a bottom metallic contact.

The above-mentioned prior art methods for forming metallic vias are encumbered by a number of disadvantages, particularly with regard to thin-film devices with layers of active organic material, for instance polymers. The layers may be extremely thin, e.g. down to some tens of nanometers and it is difficult to tune the process parameters, particularly in the thermal regime, when metal for the via plugs is deposited. Also the number of process steps entails increased production costs.

It has been found that via connections and their associated contact means in an organic electronic circuit which comprises one or more active organic dielectric materials. Such materials may have a detrimental effect upon the via connections, and this is particularly critical when the via connections actually are formed with via metal in contact with an organic material of this kind. Such via connections are commonly provided in matrix-addressable ferroelectric or electret memories wherein a layer of for instance a ferroelectric or electret polymer or copolymer is used as the memory material and surrounded on either side by sets of parallel strip-like electrodes such that the electrodes of either set are oriented substantially orthogonally to each other. The organic, e.g. ferroelectric or electret material is sandwiched between the electrode sets and forms a global layer, while memory cells are defined in the memory material between crossing electrodes. A ferroelectric or electret memory cell hence can be regarded as a ferroelectric or electret capacitor and the crossing electrodes with the organic memory material sandwiched therebetween of course are equivalent to a capacitor structure. Devices of this kind need a large number of via connections, usually provided at the edge of the device where the electrodes of the above-mentioned sets terminate in a high-density configuration, with pitches in the submicrometer range. This implies that realizing the via connections can be a tricky business. Typically the vias connect one set of the electrodes to contact means and are provided in via holes extending through the memory material which of course is a dielectric with ferroelectric or electret properties such that it can be polarized in an electric field applied between crossing electrodes of the capacitor-like structure. Moreover it has turned out that even the process of via formation, i.e. the patterning and etching of via holes as well as the deposition of the via metals, can have detrimental effects not only on the memory material, but also on the contacting electrodes, while the memory material subject to the process conditions may be able to react with both electrode and via metal chemically with a resulting deterioration in their electrical properties.

Hence it is an object of the present invention to provide via connection and associate contact means with improved quality in organic electronic circuits wherein the via connections and contact means in any case are provided interfacing relationship with active organic dielectric material which at least comprises fluorine atoms.

It is also an object of the present invention to provide via connections which are chemically, electrically and mechanically compatible with the contact means or electrode metals are provided to contact in such circuits.

The above objects as well as further features and advantages are realized with an electrical via connection and associated contact means according to the present invention which is characterized in that the second contact means comprises a first layer of chemically inert and non-reactive conducting material deposited directly on the active organic dielectric layer and a second layer of conducting material provided integrally on the first layer and in the via opening down to the first contact means, whereby the via connection between said first and second contact means extends through the active organic dielectric layer and integral with the second layer of said second contact means.

Also, the above objects as well as further features and advantages are realized with a method for manufacturing an electrical via connection and associated contact means according to the present invention which is characterized by depositing a layer of a chemically inert conducting material as a first layer of said second contact means directly on the active organic dielectric layer, forming a via opening in said first layer and through the active organic dielectric layer down to the first contact means, and depositing a layer of conducting material over the first layer as the second layer of the second contact means and through the via opening down to the first contact means, whereby the via connection between said first and second contact means is established through the active organic dielectric layer and integral with said second layer of said second contact means.

Further features and advantages shall be apparent from the appended dependent claims.

The present invention shall be better understood from the following discussion of preferred embodiments read in conjunction with the drawing figures, of which

FIG. 1 shows a cross section through a contact means with two layers according to the present invention,

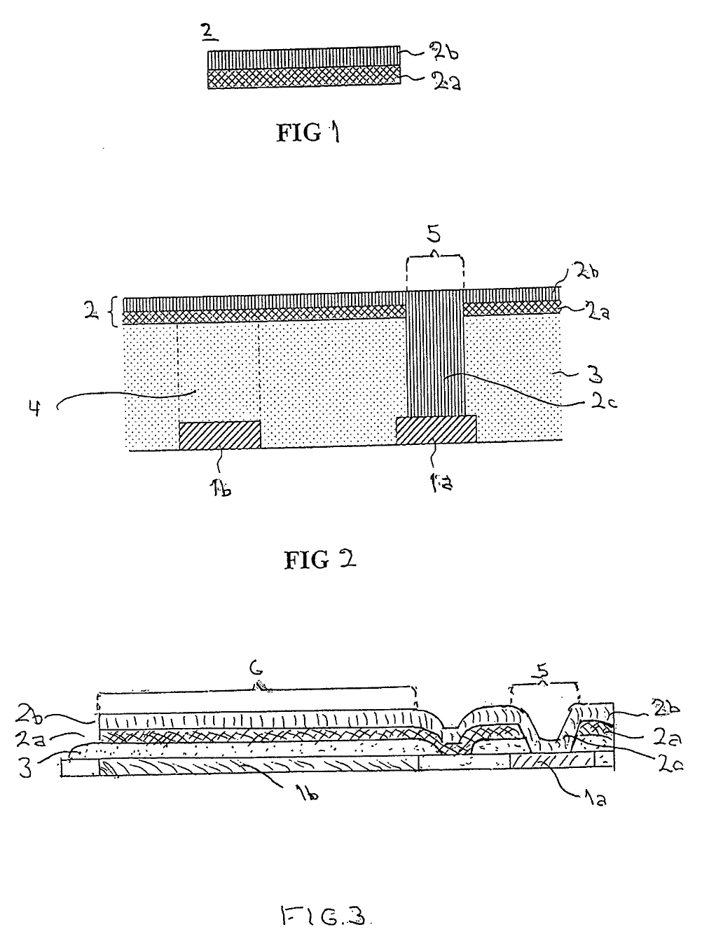

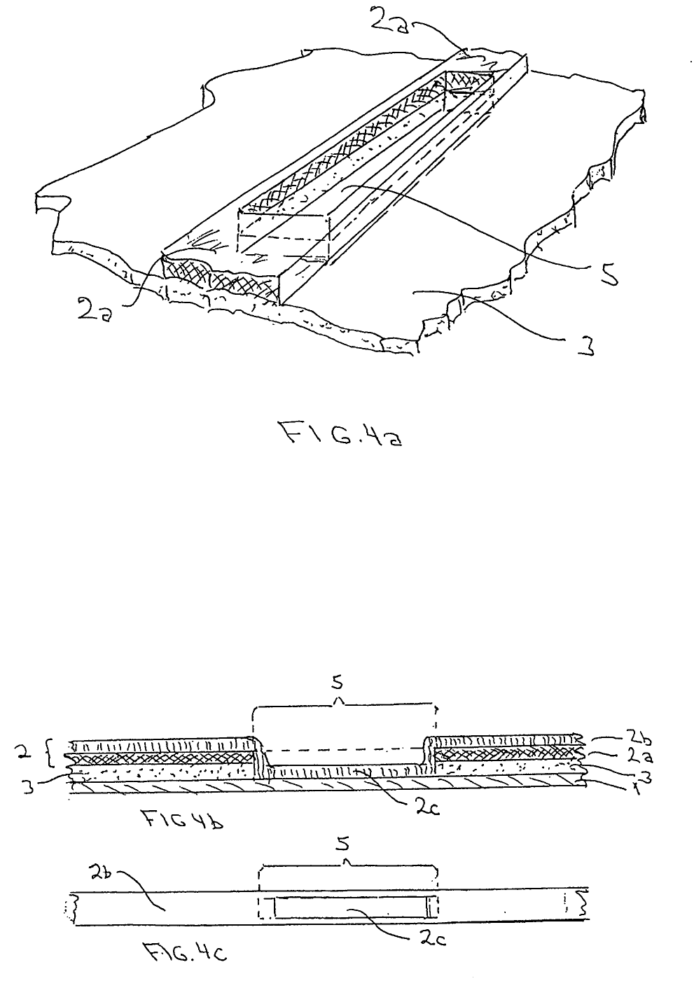

FIG. 2 a via connection according to the present invention as it for instance could be used in a matrix-addressable device with a layer of active organic dielectric material,

FIG. 3 another embodiment of a via connection and associated contact means according to the present invention,

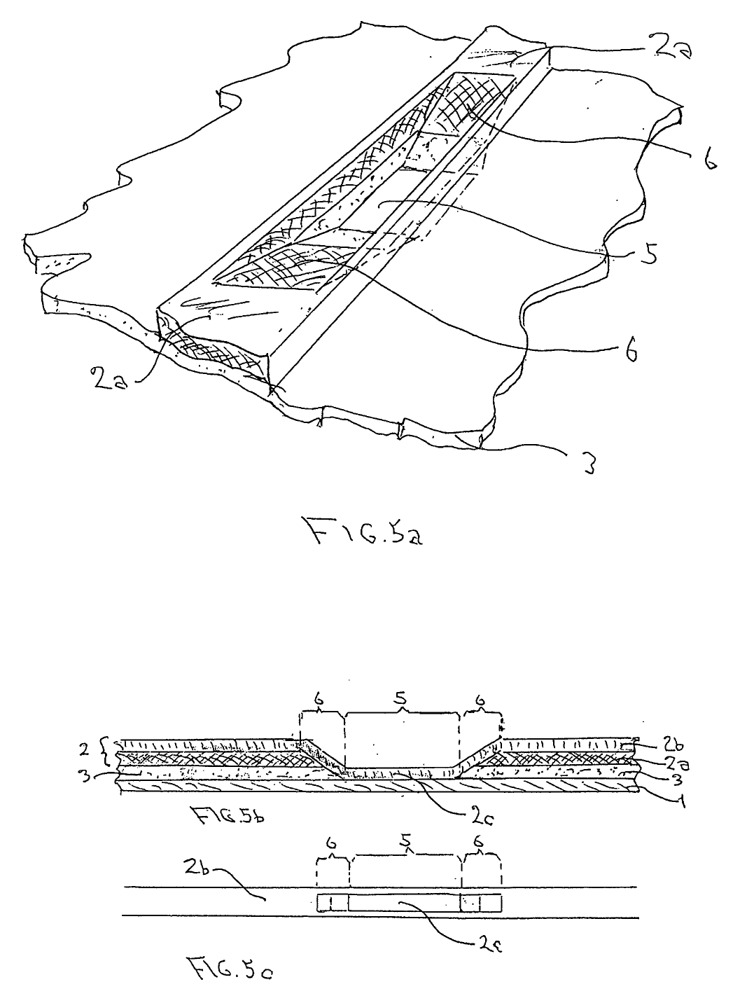

FIG. 4a a perspective view of a via opening as used in an embodiment of the present invention,

FIG. 4b a cross section of an embodiment of via connection according to the invention with a via opening as shown in FIG. 4a,

FIG. 4c a plan view of the embodiment in FIG. 4a,

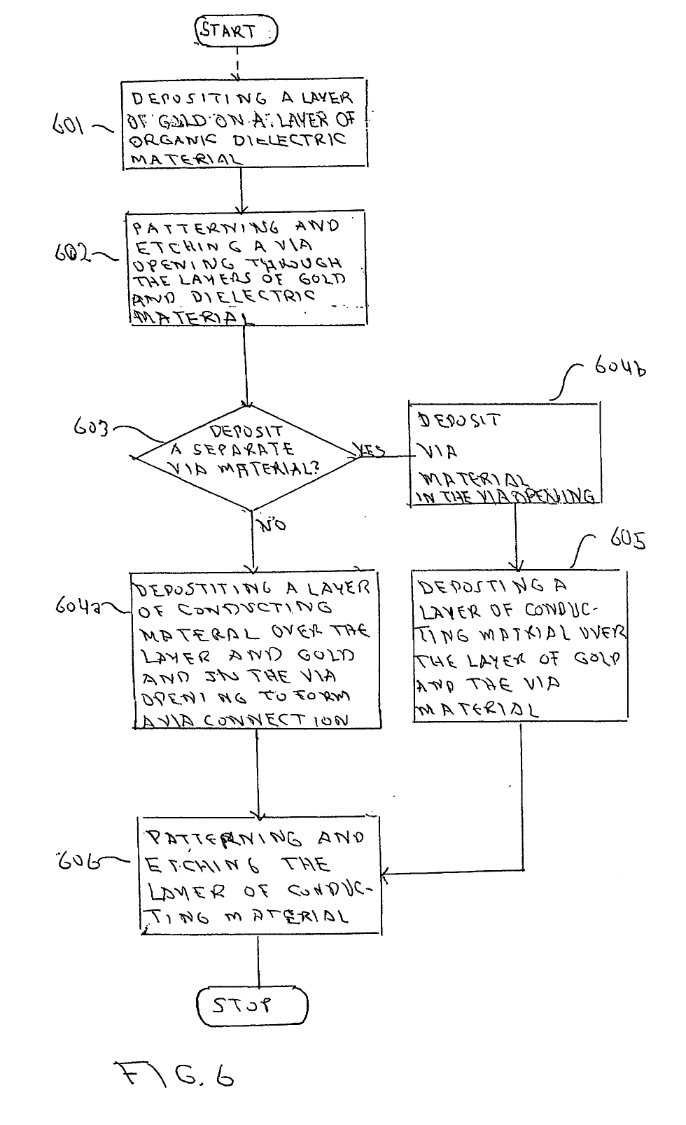

FIG. 5a a perspective view of a via opening as used in another embodiment of the present invention,

FIG. 5b a cross section of another preferred embodiment according to the present invention with a via opening as shown in FIG. 5a,

FIG. 5c a plan view of the embodiment in FIG. 5a, and

FIG. 6 a flow diagram of the manufacturing process of a via connection and associated contact means according to the present invention.

The general background of the present invention is to some extent based on the applicant's own investigations of electrode materials and deposition methods suitable for the manufacture of electronic circuits with active organic material comprising fluorine atoms. In particular the investigations have been devoted to materials for addressing electrodes and contact means in matrix-addressable ferroelectric or electret memories wherein the organic memory material is a polymer and/or copolymer based on vinylidene fluoride sandwiched between addressing electrodes. Due to interactions between the electrode metal and for instance a fluorinated ferroelectric polymer where voltage is applied to the electrodes and a electric field created in the memory material therebetween, special considerations have to be given to the selection of electrode material and methods for their deposition without adverse effects to the system electrode metal/memory material, particularly under operating conditions. As a result of the investigations there has in a copending patent application been proposed that at least the bottom electrode or a ferroelectric or electret memory circuit with an organic ferroelectric or electret memory material wherein fluorinated polymer located between the addressing electrodes, should comprise at least a layer of gold facing towards the memory material. A preferred memory material in this case is a copolymer of the type P(VDF-TrFE), i.e. polyvinylidenefluoride trifluoroethylene copolymer.

A bottom electrode should be essentially chemically inert in relation to reactive species contained in the memory material, but still the deposition of a e.g. ferroelectric polymer over the electrode may result in some detrimental surface reactions. These can, however, advantageously be alleviated by treating the exposed electrode surface chemically before depositing the memory material thereabove. The top electrode on the opposite surface of the layer of memory material, however, could be made of any suitable electrode metal, such as titanium, although some consideration had to be given to the deposition of electrode material on the memory material, particularly due to incompatible thermal or chemical regimes in the deposition process. However, given the advantageous operational results obtained with a bottom electrode of gold, as disclosed in the applicant's co-pending Norwegian patent application No. 20043163 the use of also top electrodes of gold was attempted and did indeed turn out to work well. Now it was also well known that patterning and etching holes in an organic memory material such as the above-mentioned, may have detrimental effects on the polymer material, particularly in the etching stage as such via holes in any case are made using photomicrolithography and for instance ion-reactive etching. Surprisingly it turned out that depositing a layer of a chemically inert and non-reactive conducting material before the patterning and etching of the via hole more or less eliminated all problems encountered with previous methods for forming via connections in organic dielectric materials of this kind. Particularly it turned out to be of significant advantage that after depositing the layer which could be regarded as a first layer in an electrode or contact means, the subsequent deposition of via metal could take place simultaneously with the deposition of a second layer of conducting material in the electrode or contact means, and preferably such that this conducting material and the via metal was one and the same and deposited in one and the same process step and forming a via connection integral with the electrode or contact means and at the same time ensuring a flawless contacting to the bottom electrode.

Some preferred embodiments shall now be described and discussed in order to clearly outline and emphasize the advantages of the present invention. The discussion shall be centered around the use of gold as a particularly advantageous material of the first layer of a second contact means. Generally, however, any chemically inert and non-reactive material could be used in this first layer and they could include any other similar noble metal, i.e. metals with a lower oxidation potential than silver. Hence all the platinum metals including platinum itself or palladium might be considered as suitable candidates.

FIG. 1 shows a contact means or electrode means comprising two layers 2a, 2b shown in cross section. Layer 2a is a gold layer and provided adjacent to the active organic dielectric material, while layer 2b is provided above the first layer 2a and, as already said, it need not necessarily be gold, but this however, can be an advantage.

FIG. 2 shows a cross section through an organic electronic circuit with a via connection and associated contact means according to the present invention. Herein bottom electrodes or contact means 1a, 1b are provided on a not shown substrate. The contact means 1a, 1b can advantageously be made with gold, and the exposed surface there after deposition could be chemically treated to avoid undesired surface reactions and ensure a good adhesion to the active organic dielectric material, for instance a ferroelectric or electret memory material, which may comprise fluorine atoms, and which is deposited to cover the bottom contact means 1a, 1b. Now the top electrode contact means 2 is provided such that it comprises a first layer 2a with the desired properties, e.g. made with gold adjacent to the organic material 3. A via opening 5 is now etched to the layer 2a, and down through the active organic material 3 and to the bottom contact means 1a, and then a second layer 2b of the contact means 2 and via connection 2c, i.e. the via metal, are deposited in one and the same process step such that the second layer 2b and the via connection 2c are made in the same material and provided as integral component of the circuit.

If the circuit shown in FIG. 2 is a memory circuit or a part of such a circuit in a matrix-addressable array where the active organic memory material 3 is provided in a global layer and sandwiched between the electrodes 1 and 2, a memory cell 4 is defined in the memory material 3 between crossing bottom electrodes 1b and top electrodes 2 as shown. The electrode 1a can then be an input or output line for the electrode 2 over the via connection 2c therebetween.

FIG. 3 shows a somewhat different circuit arrangement which for practical purposes can be regarded as a cross section of for instance a matrix-addressable ferroelectric memory wherein the first or bottom electrodes 1b and the top electrodes 2 are provided as strip-like electrodes respectively oriented perpendicular to each other in each of the electrode sets. The memory area 6 of the matrix-addressable array is the area wherein the ferroelectric memory material 3 functions as the active material and comprises ferroelectric memory cells 4 as capacitor-like structures with the electrodes 1a, 2 as the addressing electrodes for individual cells 4. Of course, the contact means 1a and the electrode 1b can preferably be made of gold, but particularly in this case the first layer 2a of the second electrode or contact means 2 is made of gold and deposited over the organic memory material 3 as shown. In the area of the contact means 1a provided in the bottom electrode layer a via opening 5 is etched through both the gold layer 2a and the organic material 3, whereafter the second layer 2b of the contact means 2 is deposited above the first, preferably gold layer 2a and filling the via opening 5 to form the via connection 2c through the memory material 3 and down to the contact means 1a. Again the layer 2b and the via connection 2c could be made of the same material as the layer 2a, e.g. gold, but this is not strictly necessary.

In many matrix-addressable devices, whether they be memories, displays or light-emitting arrays, the addressing electrode, i.e. the top and bottom electrodes for instance on either side of global layers of active material can be envisaged as strip-like electrodes extending across the array contacting the active material. Each electrode set is formed of parallel strip-like electrodes. The width dimension of the electrodes shall depend on an applicable design rule, but is of course always limited to the minimum feature size attainable when patterning microphotolithographical methods. In order to obtain the desired via connections and ensure a good electrical contact it is quite evident that it will be advantageous if the via opening geometry somehow can be tailored to the geometry of the contact means associated with the via connection. When a via connection shall be provided between a strip-like electrode on the top of the organic dielectric layer and down to another strip-like electrode on the opposite surface or the associated contact means anyway is elongated with width dimensions given by an applicable design rule and usually in the submicrometer range, the via openings could be designed with their geometry as disclosed in Norwegian patent application No. 20025772 filed by the present applicant. This publication discloses via holes etched with an elongated and rectangular form within the footprint of a thereabove deposited electrode metallization.

FIG. 4a shows a via hole according to the above-mentioned patent application and particularly a portion of an active organic dielectric layer with a thereabove provided strip-like electrode 2a, which in the present case corresponds to a first layer 2a or second contact means 2a. An elongated, i.e. rectangular via hole 5 is etched to the strip-like electrode 2a and the underlying dielectric organic layer 3 such that the via hole 5 appears with a geometrical form or rectangular prism. A prior art via hole of this kind can advantageously also be used in the present invention as shall be expounded in some detail in the following. A preferred embodiment where the contact means are elongate structures similar to the strip-like electrode in matrix-addressable arrays is shown in cross section in FIG. 4b. A layer of a chemically inert and non-reactive conducting material, for instance and preferably gold, forming the first layer 2a of the electrodes or contact means 2 is deposited and patterned such that the strip-like electrode is formed in the layer 1a together with a therein contained elongated via hole 5 extending through the active organic dielectric layer 3 to the bottom electrode 1, which in this case preferably also will be made of gold. Now the second layer 2b is deposited above the first layer of gold 2a and at the same time fills the via opening 5 as indicated in FIG. 4a forming the via connection 2c and ensuring an adequate contact between contact means 2 and 3. FIG. 4c shows the footprint on the via connection in plan view and the via opening now appears as a rectangular opening in the second layer 2b of the electrode or contact means 2 but, of course, extending all the way down to the bottom electrode 1.

In FIG. 5b a variant of the embodiment in FIG. 4b is showing in cross section and differs therefrom by using a via hole geometry as rendered in FIG. 5a. The via hole 5 etched and patterned in the first layer 2a and the active organic dielectric layer 3, now is formed with sloping or tapering surfaces 6 towards the side edges perpendicular to the longitudinal direction of the second layer 2a. When the second layer 2b of the electrode or contact means 2 and the via metal of the via connection 2c are deposited the elongated via opening with tapering end surfaces ensures an unimpeded metal flow and filling of via hole 5 to ensure an optimum electrical contact between contact means 1 and 2. The footprint of this variant embodiment is shown in FIG. 5c with the tapering surfaces 6 indicated as shown. Preferably via openings with this geometry is formed with a ratio such that their lengthwise dimension exceed the crosswise dimension by a factor of at least 2.5. As the via opening 5 preferably is patterned together with the strip-like electrode formed in a layer 2a, it may in principle be wholly conformal with electrode formed in layer 2a, but preferably they should be contained within the footprint of this layer to avoid any detrimental interactions with the underlying active organic dielectric material in the process. Hence it is also obvious that when resorting to conventional microphotolithography within an applicable design rule the electrode formed in the first layer 2a of the second contact means 2 shall be somewhat wider than the via opening 2c to ensure the adequate protection. By implication if the width of via hole 2c then is limited by the applicable design rule, and then of course, the strip-like electrode formed in the electrode layer 2a shall be somewhat wider, but the cost of this can in any case be regarded as negligible in terms of real estate.

It is also evident that the metallization for the second layer 2b can be provided globally and the etched and patterned to form strip-like electrodes conformal with those in layer 2a and of course also the via connections 2c.

The process steps in the manufacture of a via connection and associated contact means using a two-layer top contact means shall now be briefly discussed in connection with the flowchart shown in FIG. 6. The first layer 2a of contact means 2 is deposited in step 601, for instance by physical vapour deposition PVD to a thickness of for instance 30 to 90 nm. This first layer 2a of a chemically inert and non-reactive conductive material, preferably gold constitutes the lower or interface part of the top contact means 2 and shall act both as electrode and as protective layer for the underlying active organic dielectric material 3 during the following via opening process 602. The active organic dielectric material 3 which in this case can be regarded as a ferroelectric polymer, is also protected by this first layer 2a, e.g. of gold, during via processing. This is rendered possible due to the fact that the first layer material shall be chemically inert, as gold essentially is. As known in prior art an interlayer sometimes is provided in order to protect the layer of memory material and the via processing need not then be a problem. However, with contact means directly contacting the active organic dielectric material, via processing could be a problem, particularly if the present invention is realized on for instance passive matrix-addressable ferroelectric or electret memories with a memory material such as P(VDF-TrFE). Hence the process shown in FIG. 6 will be particularly suited for the intended object of achieving high-performance memory circuits.

The via openings are patterned in step 602 using conventional microphotolithography followed by wet or dry etching. The photoresist is then stripped off with conventional wet etching methods. A decision step 603 now offers the possibility of choosing between two separate options. The first one is realized in step 604a wherein a second layer 2b of the contact means is deposited on the top of the first layer 2a. The first and second layer then together constitute a top electrode 2b. It is of course to be understood that also this second layer 2b could be made of the same material as the first layer 2a, e.g. gold. The minimum thickness of the second layer 2b is moreover dependent on the thickness of the first layer 2a and on the deposition technique and for instance in the case of physical vapour deposition, it shall also be dependent on the degree of step coverage. This second layer 2b of the top contact means 2 now also forms the via connection 2c through the via opening 5 and thus connects the second contact means 2 with drive electronics in for instance not shown substrate circuitry with the vias 2c extending through the via openings 5 etched in step 602. The top contact means can be finally patterned in step 606 using conventional microphotolithography followed by wet etching. The photoresist may then be stripped off with wet or dry stripping methods. It should be noted that in case of dry stripping portions of the organic memory material that are not protected by the top contact means will also be stripped off and hence the method according to the invention reduces the risk of delamination between the polymer layer (for instance) and the insulating substrate. As an alternative to the last step 606 a thin layer of titanium could be deposited for use as a hard mask in the top contact means etching process The titanium layer is patterned in conventional microlithography followed by a wet or dry etching. The phototresist is then stripped off with wet or dry stripping methods.

The via metal used in the via connection 2c need not be the same as that of the second layer 2b of the second contact means 2. If so decided in step 603, a separate via metal can be deposited in the via opening 5 in step 604b before the second layer 2b is deposited. The use of separate via plugs is known in the art, and in order to improve conductivity, they could for instance be made of tungsten as common in the art and deposited by the chemical vapour or physical deposition (CVD or PVD). After depositing the via metal, the second layer 2b of the contact means 2 is deposited in step 605 and establishes the required contact. Patterning and etching of the top electrode takes place in step 610 as in the first option.

As already stated hereinabove, it is much to be preferred that the whole second contact means is made of the same chemically inert and non-reactive material, for instance gold or another noble metal, irrespective of whether the first contact means also is made of similar material. The advantage of gold in the bottom electrode has been disclosed by the applicant in the above-mentioned NO application No. 20043163 which teaches a solution to the aggravating problem of suitable electrode materials at least for the bottom electrodes in for instance ferroelectric or electret memories with memory materials based on organic fluorinated polymers or copolymers. By implication it is also a considerable simplification and advantage when both contact means are made of the same material, and then preferably gold. Also the via connection is made with materials as the contact means and in the same process step as and integral with the second contact means 2.

The essential thing and the improvement at the core of the present invention is, however, that the first layer of the second contact means always shall be a chemically inert and non-reactive material and usually it can be employed without any particular chemical treatment or tailoring to achieve the desired results, while for instance a first contact means of gold usually has to be subjected to some chemical pre-treatment before the active organic dielectric layer, i.e. the memory material, is deposited thereabove. This is due to the fact that the surface of the first contact means 1 is exposed before deposition of the organic dielectric layer. Surface reactions or structural changes may then occur and impair the functionality of the contact layer and the thereabove provided memory material. In case of the first layer 2a of the second contact means such problems do not appear, and apart from its contacting function, the first layer's primary task is to provide the desired protection of the active organic dielectric material when forming the via connections. However, one may envisage that the surface of the active organic dielectric layer 3 can be pre-treated to improve the adhesion of the layer 2a subsequently deposited thereon.

1. An electrical via connection and associated contact means in an organic electronic circuit, particularly a memory circuit, wherein a layer of an active organic dielectric material comprises single molecules, oligomers, homopolymers, copolymers, or blends or compounds thereof, wherein the via connection is provided in a via opening extending through the active dielectric layer and is connected with first and second electrical contact means respectively provided on either side of the active dielectric layer, and wherein the first contact means is provided at a bottom surface of the layer and the second contact means is provided at an opposite or top surface of the layer,
characterized in that the second contact means comprises a first layer of chemically inert and non-reactive conducting material deposited directly on the active organic dielectric layer and a second layer of conducting material provided integrally on the first layer and in the via opening down to the first contact means, whereby the via connection between said first and second contact means extends through the active organic dielectric layer and integral with the second layer of said second contact means.

2. A via connection and contact means according to claim 1, characterized in that the first layer of the associated contact means consists of a noble metal with a lower oxidation potential than silver.

3. A via connection and contact means according to claim 1, characterized in that the noble metal is gold or platinum metal, including platinum or palladium, but not limited thereto.

4. A via connection and contact means according to claim 1, characterized in that the via connection and the second layer of the associated contact means consists of a chemically inert and non-reactive conducting material.

5. A via connection and contact means according to claim 4, characterized in that the via connection and the second layer of the associated contact means consists of a noble metal with a lower oxidation potential than silver.

6. A via connection and contact means according to claim 1, characterized in that the noble metal is gold or platinum metal, including platinum or palladium.

7. A via connection and contact means according to claim 1, characterized in that the via connection and the second layer consists of a non-noble metal with higher oxidation potential than silver.

8. A via connection and contact means according to claim 1, characterized in that the via connection and the second layer consist of the same conducting material.

9. A via connection and contact means according to claim 1, characterized in that the via connection and the second layer consist of dissimilar conducting materials.

10. A via connection and contact means according to claim 1, characterized in that the via connection is provided as a protruding portion of the second layer of the second contact means and extends through the via opening to contact the first contact means.

11. A via connection and contact means according to claim 1, characterized in that the via connection is provided as a portion of the second layer of the second contact means and deposited over at least a portion of one or more side edges of the via opening and extending across the bottom thereof to contact the first contact means.

12. A via connection and contact means according to claim 1, characterized in that at least one of said contact means is an electrode interfacing the organic dielectric layer.

13. A via connection and contact means according to claim 12, characterized in the said at least one electrode is a strip-like electrode.

14. A via connection and contact means according to claim 1, characterized in that at least one of said contact means is a contact pad.

15. A via connection and contact means according to claim 1, characterized in that said first contact means consists of gold.

16. A method for manufacturing an electrical via connection and an associated contact means in an organic electronic circuit, particularly a memory circuit, wherein a layer of an active organic dielectric material comprises single molecules, oligomers, homopolymers, copolymers, or blends or compounds thereof, wherein the via connection is provided in a via opening extending through the active dielectric layer and is connected with first and second electrical contact means respectively provided on either side of the active dielectric layer, and wherein the first contact means is provided at a bottom surface of the layer and the second contact means being provided an opposite or top surface of the layer,
characterized by depositing a layer of a chemically inert conducting material as a first layer of said second contact means directly on the active organic dielectric layer, forming a via opening in said first layer and through the active organic dielectric layer down to the first contact means, and depositing a layer of conducting material over the first layer as the second layer of the second contact means and through the via opening down to the first contact means, whereby the via connection between said first and second contact means is established through the active organic dielectric layer and integral with said second layer of said second contact means.

17. A method for manufacturing an electrical via connection and associated contact means according to claim 16,
characterized by selecting a noble metal with lower oxidation potential than silver as the conducting material of the first layer.

18. A method for manufacturing an electrical via connection and associated contact means according to claim 17,
characterized by selecting the noble metal as gold or platinum metal, including platinum or palladium, but not limited thereto.

19. A method for manufacturing an electrical via connection and associated contact means according to claim 16,
characterized by selecting a noble metal with a lower oxidation potential than silver as the material of the via connection and the second layer of said second contact means.

20. A method for manufacturing an electrical via connection and associated contact means according to claim 19,
characterized by the noble metal being gold or a platinum metal such as platinum or palladium, but not limited thereto.

21. A method for manufacturing an electrical via connection and associated contact means according to claim 10,
characterized by selecting a non-noble metal with a higher oxidation potential than silver as the material of the via connection and the second layer of said second contact means.
